(19) United States
(12) Patent Application Publication
(10) Pub. No.: US 2025/0201716 A1
(43) Pub. Date: Jun. 19, 2025

(54) TANTALUM ELECTRODE WITH TANTALUM NITRIDE LINER AS RIE DIFFUSION BARRIER

(71) Applicant: INTERNATIONAL BUSINESS MACHINES CORPORATION, ARMONK, NY (US)

(72) Inventors: Luxherta Buzi, Chappaqua, NY (US); Pouya Hashemi, Purchase, NY (US); Christopher Peter D'Emic, Ossining, NY (US)

(21) Appl. No.: 18/539,166

(22) Filed: Dec. 13, 2023

(51) Int. Cl. H01L 23/532; H01L 21/3065; H01L 21/768; H01L 23/528

(52) U.S. Cl. CPC H01L 23/53238; H01L 21/3065; H01L 21/76865; H01L 21/76885; H01L 23/5283

(57) ABSTRACT

A semiconductor device and method of manufacture prevents the diffusion of halogen gases from reactive ion etching to prevent the formation of hillocks. The semiconductor device includes a substrate, and a metal layer in contact with the substrate. An electrode made of tantalum is arranged on top of the metal layer, and a diffusion barrier layer is arranged between the top electrode and the metal layer. The diffusion barrier layer is formed of a halogen-blocking material.

### BACKGROUND

### Technical Field

The present disclosure is generally related to semiconductors with multiple metallization layers, and more particularly, to structures and fabrication methods of such semiconductors.

### Description of the Related Art

There has been an increase in the use of vertically stacked semiconductors in which a reactive ion etching (RIE) is performed on a patterned substrate. The RIE process involves creating a plasma from one or more halogen gases.

### SUMMARY

In an embodiment, a semiconductor device includes a substrate, and a metal layer in contact with the substrate. An electrode made of tantalum (Ta) is arranged on top of the metal layer. A diffusion barrier layer is arranged between the electrode and the metal layer, wherein the diffusion barrier layer is made of a halogen-blocking material.

In an embodiment, which may be combined with the preceding embodiment, the diffusion barrier layer is constructed of tantalum nitride (TaN).

In one embodiment, which can be combined with one or more preceding embodiments, the diffusion barrier layer has a height in a range of 8 to 10 nm.

In one embodiment, which can be combined with one or more preceding embodiments, the diffusion barrier layer has a height in a range of substantially 8 to 20 nm.

In one embodiment, which can be combined with one or more preceding embodiments, an etch stop layer is arranged between the diffusion barrier layer and the metal layer, the etch stop layer extending over an upper portion of the substrate.

In one embodiment, which can be combined with one or more preceding embodiments, the etch stop layer is constructed of ruthenium (Ru), and a magnetic tunnel junction stack is formed between the metal layer and the etch stop layer.

In one embodiment, which can be combined with one or more preceding embodiments, the metal layer is made of copper (Cu).

In one embodiment, which can be combined with one or more preceding embodiments, the substrate is a patterned substrate.

In one embodiment, which can be combined with one or more preceding embodiments, the substrate is made of silicon (Si) or silicon nitride (SiN).

In one embodiment, a method of manufacturing a semiconductor device includes arranging a metal layer on a substrate, arranging a diffusion barrier layer made of a halogen-blocking material on the metal layer, and arranging an electrode on top of the metal layer. Reactive ion etching is performed to trim the width of the Ta electrode and form a pillar.

In an embodiment, which may be combined with the preceding embodiment, the arranging of the diffusion barrier layer further includes providing a TaN diffusion barrier layer having a height in a range of about has a height in a range of 8 to 20 nm.

In one embodiment, which can be combined with one or more preceding embodiments, the arranging of the diffusion barrier layer includes providing a TaN diffusion barrier layer having a height in a range of substantially 8 to 10 nm.

In one embodiment, which can be combined with one or more preceding embodiments, an SiOx layer is provided on the Ta electrode.

In one embodiment, which can be combined with one or more preceding embodiments, the method includes providing an organic planarization layer (OPL) on an upper surface of the SiOx layer.

In one embodiment, which can be combined with one or more preceding embodiments, the method includes providing an anti-reflective coating layer on an upper surface of the OPL.

In one embodiment, which can be combined with one or more preceding embodiments, the method includes providing a photoresist (PR) layer on a portion of an upper surface of the anti-reflective coating.

In one embodiment, which can be combined with one or more preceding embodiments, the method includes performing reactive ion etching (RIE) to trim a width of the Ta electrode.

In one embodiment, a semiconductor device includes a metal layer, an electrode made of tantalum (Ta) arranged on top of the metal layer; and a diffusion barrier layer arranged between the electrode and the metal layer, wherein the diffusion barrier layer comprises a halogen gas-blocking material. A thickness of the diffusion barrier layer is 8 to 10 nm.

In an embodiment, which may be combined with the preceding embodiment, an etch stop layer an etch stop layer is arranged between the diffusion barrier layer and the metal layer, and the electrode and the diffusion barrier layer are etched into a pillar shape by reactive ion etching (RIE).

In one embodiment, which can be combined with one or more preceding embodiments, the diffusion barrier layer blocks fluorine (F), chlorine (Cl), and bromine (Br) gases from passing to the metal layer.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a front view of a stacked semiconductor.

FIG. 2 illustrates a front view of a stacked semiconductor having a diffusion barrier layer, and prior to an RIE application, consistent with an illustrative embodiment.

FIG. 3 illustrates a front view of a stacked semiconductor after the RIE application, consistent with an illustrative embodiment.

FIG. 4A is a photo a Cu surface of a semiconductor device without a diffusion barrier layer such as in FIG. 1.

FIG. 4B is a photo of a CU surface of a semiconductor device with a diffusion barrier layer consistent with the illustrative embodiment shown in FIG. 2.

FIG. 5 is a flowchart illustrating a method of manufacturing a semiconductor device consistent with an illustrative embodiment.

### DETAILED DESCRIPTION

In the following detailed description, numerous specific details are set forth by way of examples to provide a thorough understanding of the relevant teachings. However, it is to be understood that the present teachings may be practiced without such details. In other instances, well-known methods, procedures, components, and/or circuitry have been described at a relatively high-level, without detail, to avoid unnecessarily obscuring aspects of the present teachings. It is also to be understood that the present disclosure is not limited to the depictions in the drawings, as there may be fewer elements or more elements than shown and described.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

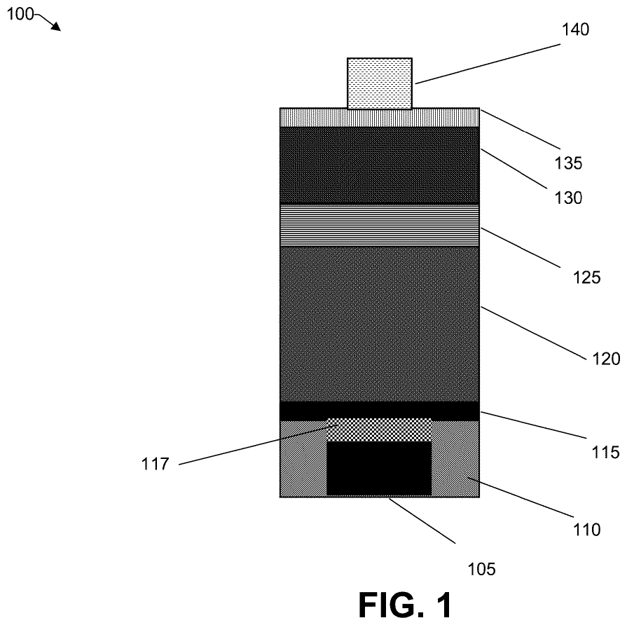

As described more fully below, the methods and devices disclosed herein may be formed in and above bulk substrates such as Si and/or silicon on insulator (SOI) substrates. In the illustrative example depicted herein in FIG. 1, the semiconductor device is depicted as being on a Si substrate. It is to be understood that other types as substrates may be used as well, including, without limitation, silicon dioxide, aluminum oxide, sapphire, germanium, gallium arsenide (GaAs), an alloy of silicon and germanium, or indium. In addition, it is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

The substrate can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments of the invention, the substrate can include a buried oxide layer in a silicon-on-insulator (SOI) configuration. The buried oxide layer can be made of any suitable dielectric material, such as, for example, a silicon oxide. In some embodiments of the invention, the buried oxide layer is formed to a thickness of about 10-200 nm, although other thicknesses are within the contemplated scope of the invention. In some embodiments of the invention, the semiconductor structure can also be formed without the buried oxide layer. In that case, an STI (shallow trench isolation) will be formed to isolate device from device.

In one or more illustrated embodiments of the disclosure, reactive ion etching (RIE) is used. Accordingly, etching mask layer(s) may be provided, and the layers that are not protected thereby are removed. For example, as is understood by those of ordinary skill in the art, a mask layer, sometimes referred to as a photomask, may be provided by forming a layer of photoresist material on the amorphous SiO₂ layer, exposing the photoresist material to a pattern of light, and developing the exposed photoresist material. An etching process, such as a reactive ion etch (RIE), may be used to form patterns (e.g., openings) by removing portions of the amorphous SiO₂ layer and a diffusion barrier, up to the top surface of a first electrode layer. After etching, the mask layer may be removed using a conventional plasma ashing or a stripping process. Accordingly, the pattern of the mask layer facilitates the removal of the amorphous SiO₂ layer and a diffusion barrier layer, in areas where the mask layer has not been deposited, thereby leaving behind two regions. A similar process may be used to pattern the electrode layer (e.g., before a conductive oxide diffusion barrier is provided thereon).

A person of ordinary skill in the art will appreciate that additional embodiments and combinations may exist in addition to those described herein.

### Overview

The present disclosure is generally directed to a device and a method of manufacturing a semiconductor with a diffusion barrier to prevent hillock formation. When a semiconductor stack is fabricated, a reactive ion etching (RIE) process may be applied to form a patterned substrate. More particularly, RIE is a dry etching process used to create patterns on semiconductor wafers. During the RIE process, a radio frequency power is applied to a gas mixture in a vacuum chamber to create a plasma. The gas mixture is typically formed of one or more halogen gases. Halogen gases are a group of five non-metallic elements that include that include fluorine (F), chlorine (CI), bromine (Br), iodine (I), and astatine (At). Typically, the halogen gases used in an RIE process are Cl, F, and Br. The halogen gases are highly reactive and form salts when they react with metals.

One of the problems with the RIE process is that the halogen gases may pass through an etch stop layer (e.g., an Ru layer) and interact with buried metal lines to cause the formation of hillocks (e.g., small protrusions on the metal layer) on a metal layer (such as a Cu layer). Hillocks may be caused by stress-induced boundary migration during the RIE process, and may cause a decrease in semiconductor yield, short circuits, and overall reduced reliability.

According to some of the illustrative embodiments of the present disclosure, the addition of a TaN diffusion barrier layer in conjunction with a Ta electrode serves as a barrier for halogens diffusing through an etch stop layer and causing the formation of hillocks on a Cu layer. Thus, the method of semiconductor fabrication and the semiconductor device disclosed herein protect buried Cu interconnects, and mitigates Cu damage caused by the formation of hillocks.

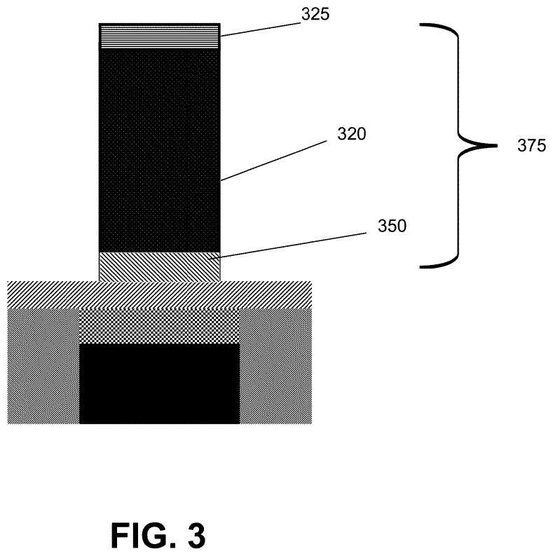

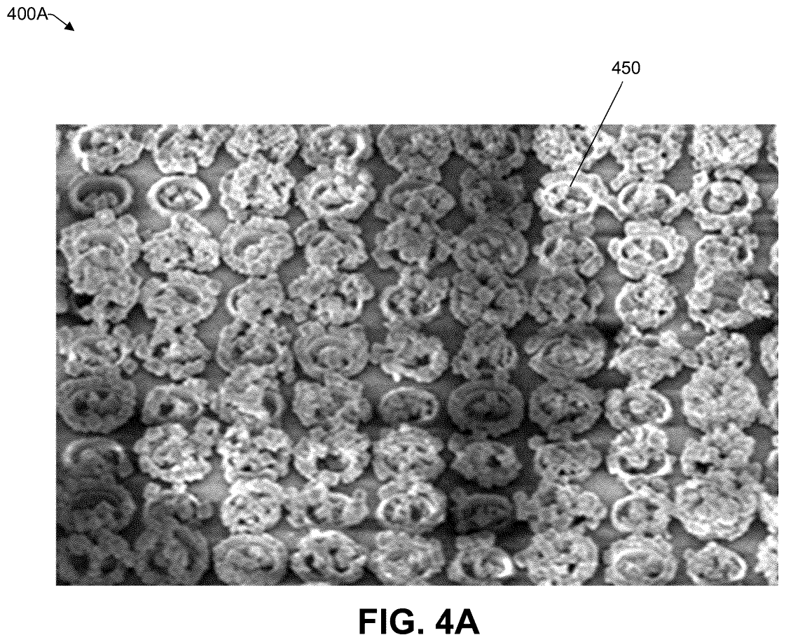

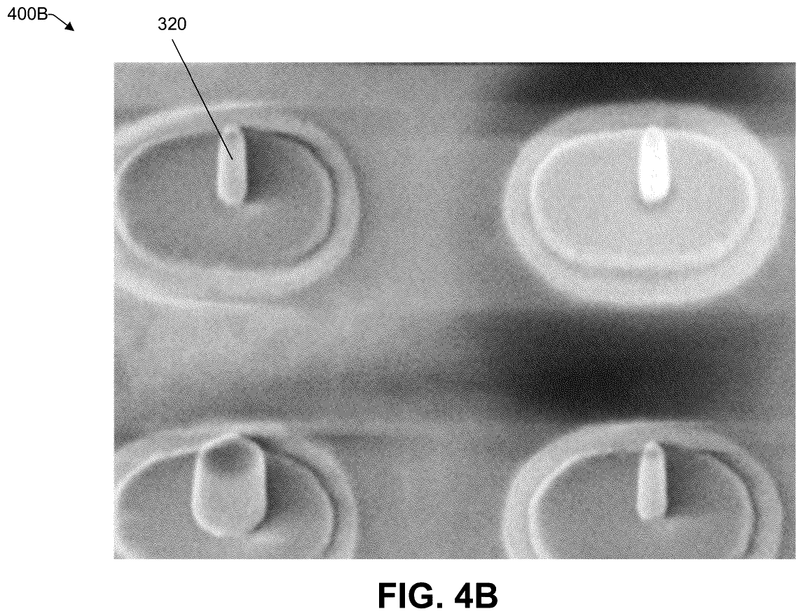

FIG. 1 is a view of a semiconductor stack. The semiconductor 100 includes a metal layer 105 on a substrate 110, an Ru etch stop layer 115, a magnetic tunnel junction (MTJ) stack 117, an electrode layer 120, an SiOx layer 125, an organic planarization layer (OPL) 130, an anti-reflective coating (siARC) 135, and a photoresist layer 140. Reactive Ion etching (RIE) is performed on the semiconductor 100 to trim the width of the electrode layer 120 and form a pillar structure (375 in FIG. 3). However, the RIE process includes generating a plasma from a halogen gas, and some of the halogen gas diffuses through the etch stop layer 115 and reacts with the metal layer 105 to cause migration of the metal and form unwanted hillocks (shown in FIG. 4A). The hillocks decrease the semiconductor yield, and contribute to the failure rate of the semiconductor. As discussed hereinbelow, the present disclosure provides an additional layer that acts as a diffusion barrier that prevents the halogen gases used in the RILE process from forming hillocks on the metal layer 105.

### Example Embodiment(s)

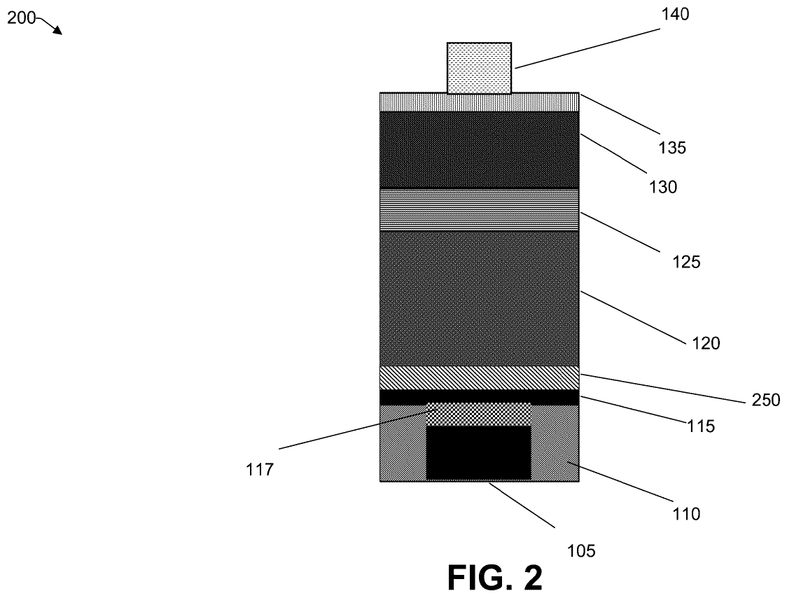

FIG. 2 illustrates a front view of a stacked semiconductor having a diffusion barrier layer, and prior to an RIE application, consistent with an illustrative embodiment. The semiconductor 200 is a stack with layers shown in FIG. 1, namely a metal layer 105 in contact with a substrate 110, an Ru etch stop layer 115, an MTJ stack 117, an electrode layer 120, an SiOx layer 125, an organic planarization layer (OPL) 130, an anti-reflective coating (siARC) 135, and a photoresist layer 140. The MTJ stack 117 is formed of two ferromagnetic layers separated by a thin insulating layer. In addition, the semiconductor 200 includes a diffusion barrier layer 250 constructed of TaN. The diffusion barrier layer shown has a thickness of about 10 nm. However, the diffusion barrier layer 250 may have a thickness range ranging from about 8 nm to 20 nm. The diffusion barrier layer reduces or prevents the halogen gases from reacting with copper lines and the metal layer 105 to cause the formation of hillocks by the partial migration of the metal.

FIG. 3 illustrates a front view of a stacked semiconductor 300 after the RIE process, consistent with an illustrative embodiment. RIE is performed to form a pillar structure 375, shown in FIG. 3. The photoresist layer 140, the OPL 130 and the siARC layers 135 are all removed. The semiconductor 300 shows the diffusion barrier layer 350 and the SiOx layer 325 have been trimmed along with the electrode layer 120 (FIGS. 1 and 2) as part of the pillar structure 375.

FIG. 4A is a photo of a Cu surface of a semiconductor device 400A without a diffusion barrier layer such as in FIG. 1. It can be seen from the photo that there are small formations of electrodes with the hillocks 450 on their surface. As discussed above, the hillocks are unwanted and degrade the operation of the semiconductors, as well as reduce the semiconductor yield and cause reliability issues in operation from short-circuiting that may occur.

FIG. 4B is a photo of a Cu surface of a semiconductor device 400B with a diffusion barrier layer consistent with the illustrative embodiment shown in FIG. 2. FIG. 4B illustrates that the pillar structure 375 is formed on a relatively hillock-free surface due to the inclusion of the diffusion barrier layer 250 (FIG. 2) used in the construction of the semiconductor.

### Example Process

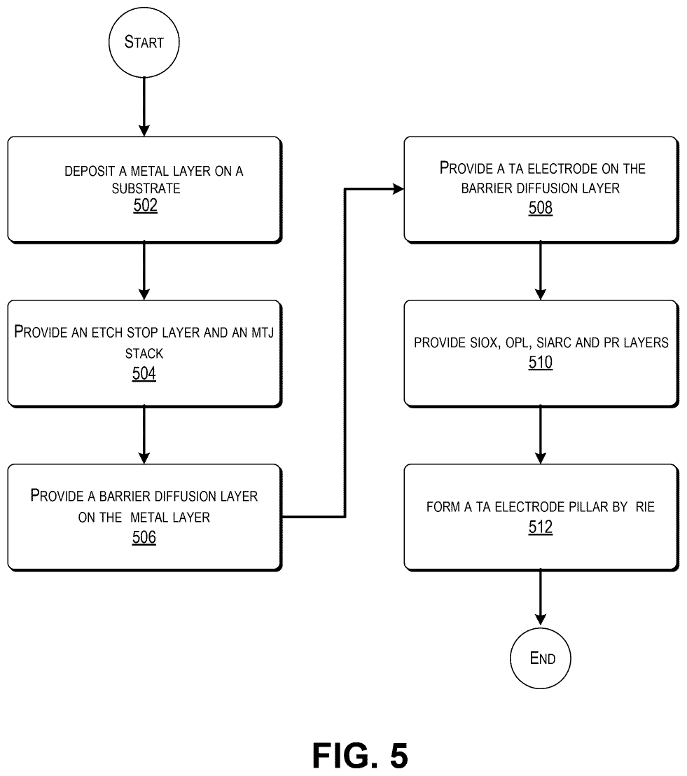

With the foregoing overview of the example architecture, it may be helpful now to consider a high-level discussion of an example process. To that end, FIG. 5 is a flowchart illustrating a method of fabricating a semiconductor with an RIE diffusion barrier, consistent with an illustrated embodiment.

A metal layer 105 (see FIG. 2) is deposited on a substrate 110 (operation 502). As disclosed herein above, in this embodiment the metal layer 105 is made of Cu, and the substrate 110 may be formed of SiN. However, the semiconductor structure is not limited to these materials, as disclosed above regarding the various types of substrates that may be used. Metal layers other than Cu, or alloys may also be used, but will impact the efficacy of operation.

An etch stop layer and a magnetic tunnel junction (MTJ) stack are deposited on the metal layer 105 (operation 504). The etch stop layer 115 shown in FIG. 2 is constructed of Ru, but it is possible to use other suitable materials. For example, other metals with a high selectivity to the RIE chemistry used to etch the electrode layer 120. The MTJ stack 117 (shown in FIGS. 1 and 2) is formed of two ferromagnetic layers separated by a thin insulating layer. The MTJ stack 117 is arranged on the metal layer 105 and the etch stop layer 115 is arranged on the MTJ stack 117.

A diffusion barrier layer is provided on the metal layer (operation 506). As shown in FIG. 2, a diffusion barrier layer 250 is arranged on the etch stop layer 115. The diffusion barrier layer is constructed of TaN, and may have a thickness (i.e., height) of 10 nm. There are other ranges of thickness of the diffusion barrier layer 250 that may be used (e.g., 8 to 10 nm, 8-20 nm).

A Ta electrode is provided on the diffusion barrier layer (operation 508). As shown in FIG. 2, the electrode layer 120 is deposited on the diffusion barrier layer 250. As discussed above, the diffusion barrier layer of TaN acts to prevent halogen gases from forming hillocks on the metal layer 105.

The SiOx layers, OPL, siARC and PR layers are provided (operation 510). These layers collectively provide for a further operation removing the photoresist, and other mask layers to form the pillar structure 375 shown in FIG. 3.

RIE is performed to trim the width of the Ta electrode (operation 512) and form a TA pillar electrode 125-1 such as shown in FIG. 3. Again, referring to FIG. 4B, the electrode pillar(s) 320 are shown with hillock free surfaces.

The method ends after operation 512, although there may be additional operations performed to ready the semiconductor for use.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to better explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device comprising:
a substrate;
a metal layer in contact with the substrate;
an electrode comprising tantalum (Ta) arranged on top of the metal layer;
a diffusion barrier layer arranged between the electrode and the metal layer, wherein the diffusion barrier layer comprises a halogen-blocking material.

2. The semiconductor device according to claim 1, wherein the diffusion barrier layer comprises tantalum nitride (TaN).

3. The semiconductor device according to claim 2, wherein the diffusion barrier layer has a height in a range of substantially 8 to 10 nm.

4. The semiconductor device according to claim 2, wherein the diffusion barrier layer has a height in a range of 8 to 20 nm.

5. The semiconductor device according to claim 4, further comprising an etch stop layer arranged between the diffusion barrier layer and the metal layer, the etch stop layer extending over an upper portion of the substrate.

6. The semiconductor device according to claim 5, wherein the etch stop layer comprises ruthenium (Ru), and further comprising a magnetic tunnel junction stack formed between the metal layer and the etch stop layer.

7. The semiconductor device according to claim 1, wherein the metal layer comprises copper (Cu).

8. The semiconductor device according to claim 1, wherein the substrate comprises a patterned substrate.

9. The semiconductor device according to claim 1, wherein the substrate comprises silicon (Si) or silicon nitride (SiN).

10. A method of manufacturing a semiconductor device, the method comprising:
arranging a metal layer on a substrate;
arranging a diffusion barrier layer constructed of a halogen-blocking material on the metal layer; and
arranging an electrode constructed of tantalum (Ta) on top of the diffusion barrier layer; and
performing reactive ion etching (RIE) to trim a width of the Ta electrode to form a pillar.

11. The method according to claim 10, wherein the arranging of the diffusion barrier layer further comprises providing a TaN diffusion barrier layer having a height in a range of 8 to 20 nm.

12. The method according to claim 10, wherein arranging of the diffusion barrier layer further comprises providing a tantalum nitride (TaN) diffusion barrier layer having a height in a range of about 8 to 10 nm.

13. The method according to claim 12, further comprising providing an etch stop layer arranged between the diffusion barrier layer and the metal layer, the etch stop layer extending over an upper portion of the substrate.

14. The method according to claim 13, further comprising providing a silicon oxide (SiOx) layer on top of the Ta electrode.

15. The method according to claim 14, further comprising providing an organic planarization layer (OPL) on an upper surface of the SiOx layer.

16. The method according to claim 15, further comprising providing an anti-reflective coating layer on an upper surface of the OPL.

17. The method according to claim 16, further comprising providing a photoresist (PR) layer on a portion of an upper surface of the anti-reflective coating layer.

18. A semiconductor device comprising:
a metal layer;
a magnetic tunnel junction stack arranged on the metal layer;
an electrode comprising tantalum (Ta) arranged on top of the metal layer;
a diffusion barrier layer arranged between the electrode and the metal layer, wherein the diffusion barrier layer comprises a halogen gas-blocking material, wherein a thickness of the diffusion barrier layer is 8 to 10 nm.

19. The semiconductor device according to claim 18, further comprising an etch stop layer arranged between the diffusion barrier layer and the metal layer, and wherein the electrode and the diffusion barrier layer are etched into a pillar shape by reactive ion etching (RIE).

20. The semiconductor device according to claim 18, wherein the diffusion barrier layer blocks fluorine (F), chlorine (CI), and bromine (Br) gases from passing to the metal layer.
